(19) United States
(12) Patent Application Publication
(10) Pub. No.: US 2006/0006490 A1
(43) Pub. Date: Jan. 12, 2006

(54) Method of fabricating a semiconductor device

(75) Inventor: Yuuki Doi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/174,525

(22) Filed: Jul. 6, 2005

(30) Foreign Application Priority Data
Jul. 7, 2004 (JP) P2004-200057

(51) Int. Cl. H01L 29/423

(52) U.S. Cl. 257/495

(57) ABSTRACT

A semiconductor device capable of moderating concentration of surge current and thereby improving surge voltage resistance is proposed, the device comprising a P-well 12 formed by diffusing an impurity into a P⁺-type semiconductor substrate 10; an outer peripheral P⁺-type diffusion layer 14 formed by diffusing an impurity along the outer periphery of the P-well 12 with a concentration higher than that in the P-well; P⁺-type diffusion layers 16 formed in regions surrounded by the outer peripheral P⁺-type diffusion layers 14, by diffusing an impurity with a concentration higher than that in the P-well 12, arranged so that the centers thereof are aligned in line in one direction in a plan view, and so that every second centers thereof are aligned in line in the direction normal to the one direction; and N⁺-type diffusion layers 18 continuously formed between the outer peripheral P⁺-type diffusion layer 14 and the P⁺-type diffusion layers 16, and between adjacent ones of the P⁺-type diffusion layers, by diffusing an impurity with a high concentration.

This application is based on Japanese patent application No. 2004-200057 the content of which is incorporated hereinto by reference.

### DISCLOSURE OF THE INVENTION

2. Field of the Invention

The present invention relates to a semiconductor device, and in particular to a semiconductor device used for a protective element protecting an internal circuit.

2. Description of the Related Art

There is known a diode used as a protective element protecting an internal circuit, typically as described in Japanese Laid-Open Patent Publication No. 5-235379.

In the diode, as shown in FIGS. 6A to 6C, lattice-patterned N⁺-type diffusion layers 601 are arranged on one main surface of a P-type semiconductor substrate 600, P⁺-type diffusion layers 602 are arranged at around the lattice and at regions partitioned by the lattice so as to oppose with the lattice as being equally spaced therefrom. An input terminal 603 is connected to the N⁺-type diffusion layers 601, and a ground (GND) 604 is connected to the P⁺-type diffusion layers 602.

The protective diode element is known to exhibit more excellent ability as a protective element when it has a lower resistance. A larger protective ability is obtained by making area of protective diode elements D1 to D8, needing only a short path for the fabrication through the high-resistivity P-type semiconductor substrate 600, larger than area of protective diode elements D9 to D12, needing a long path for the fabrication therethrough. The technique described in Japanese Laid-Open Patent Publication No. 5-235379 that the protective diodes shall be made with a lattice pattern disposing the P⁺-type diffusion layers 602 as the opposing planes, and then the area of the low-resistivity protective diode elements shall be increased to thereby increase the opposing area with the N⁺-type diffusion layers 601, so that a protective ability shall be improved.

### SUMMARY OF THE INVENTION

However, the protective diode structure, having the N⁺-type diffusion layers 601 arranged therein with the lattice pattern, based on the technique described in Japanese Laid-Open Patent Publication No. 5-235379, may be degraded in the surge voltage resistance, because point “A” in FIG. 6A will have current concentrated from four P⁺-type diffusion layers 602 disposed around a single intersection (corner portion) of the N⁺-type diffusion layers 601.

According to the present invention, there is provided a semiconductor device comprising:

a first-conductivity-type outer peripheral high concentration diffusion layer formed in a first-conductivity-type semiconductor substrate by diffusing therein an impurity with a high concentration along the outer periphery of a predetermined region;

first-conductivity-type high concentration diffusion layers formed in regions surrounded by the first-conductivity-type outer peripheral high concentration diffusion layer, by diffusing an impurity with a high concentration, arranged so that the centers thereof are aligned in line in one direction in a plan view, and so that every second centers thereof are aligned in line in the direction normal to the one direction; and

second-conductivity-type high concentration diffusion layers continuously formed between the first-conductivity-type outer peripheral high concentration diffusion layer and the first-conductivity-type high concentration diffusion layers, and between adjacent ones of the first-conductivity-type high concentration diffusion layers, by diffusing an impurity with a high concentration.

According to the present invention, there is also provided a semiconductor device comprising:

a first-conductivity-type buried diffusion layer formed in a first-conductivity-type semiconductor substrate by diffusing therein an impurity;

a first-conductivity-type outer peripheral high concentration diffusion layer formed along the outer periphery of the first-conductivity-type buried diffusion layer, by diffusing an impurity with a concentration higher than that in the first-conductivity-type buried diffusion layer;

first-conductivity-type high concentration diffusion layers formed in regions surrounded by the first-conductivity-type outer peripheral high concentration diffusion layer, by diffusing an impurity with a concentration higher than that in the first-conductivity-type buried diffusion layer, arranged so that the centers thereof are aligned in line in one direction in a plan view, and so that every second centers thereof are aligned in line in the direction normal to the one direction; and

second-conductivity-type high concentration diffusion layers continuously formed between the first-conductivity-type outer peripheral high concentration diffusion layer and the first-conductivity-type high concentration diffusion layers, and between adjacent ones of the first-conductivity-type high concentration diffusion layers, by diffusing an impurity with a high concentration.

In these semiconductor devices, the inner peripheral portion of the first-conductivity-type outer peripheral high concentration diffusion layer may be formed as being projected, in a plan view, at a position opposing to a recessed portion configured by the outer peripheral portion of the second-conductivity-type high concentration diffusion layers.

In these semiconductor devices, each of the first-conductivity-type high concentration diffusion layers may be formed to have a square outer peripheral profile. Each of the first-conductivity-type high concentration diffusion layers may also be formed to have a hexagonal outer peripheral profile. Each of the first-conductivity-type high concentration diffusion layers may sill also be formed to have a circular outer peripheral profile.

In any one of the above-described semiconductor devices, distance between the first-conductivity-type high concentration diffusion layers and the second-conductivity-type high concentration diffusion layers may be uniform over the entire region of the device.

In any one of the above-described semiconductor devices, width of the second-conductivity-type high concentration diffusion layers may be uniform over the entire region of the device.

In any one of the above-described semiconductor devices, the width of the first-conductivity-type high concentration diffusion layers may be equal to the distance between the first-conductivity-type high concentration diffusion layers and the second-conductivity-type high concentration diffusion layers.

In any one of the above-described semiconductor devices, the formula (1) below:
d1=d2=d3=d4/3 (1)
may be satisfied, assuming the width of the first-conductivity-type high concentration diffusion layers as d1, the width of the second-conductivity-type high concentration diffusion layer as d2, the distance between the first-conductivity-type high concentration diffusion layer and the second-conductivity-type high concentration diffusion layers as d3, and the distance of the second-conductivity-type high concentration diffusion layers as d4.

This configuration successfully reduces the number of first-conductivity-type high concentration diffusion layers disposed around a single branching point (corner portion) of the second-conductivity-type high concentration diffusion layers to as small as 3 or less, so that current concentrated at the individual branching points from the surrounding first-conductivity-type high concentration diffusion layers can be moderated as compared with the conventional case, and the surge voltage resistance can be improved.

By configuring the edge of the second-conductivity-type high concentration diffusion layers as having a recessed portion, and by forming the first-conductivity-type high concentration diffusion layers as being projected at the position opposing with the recessed portion, it is made possible to increase the total length (also referred to as “perimeter”) of the opposing edges of both diffusion layers. This makes it possible to improve the surge voltage resistance even in a semiconductor device of the same area.

Reduction in geometrical non-uniformity in the semiconductor device typically so as to satisfy the equation (1) in the above successfully equalizes the width of both diffusion layers and the distance between the first-conductivity-type high concentration diffusion layers and the second-conductivity-type high concentration diffusion layers so as to eliminate the geometrical non-uniformity, so that it is made possible to uniformly spread current from the first-conductivity-type high concentration diffusion layers, and to more effectively improve the surge voltage resistance.

The present invention therefore makes it possible to moderate concentration of surge current, and to thereby improve the surge voltage resistance.

### BRIEF DESCRIPTION OF THE DRAWINGS

The above and other objects, advantages and features of the present invention will be more apparent from the following description taken in conjunction with the accompanying drawings, in which:

FIGS. 1A and 1B are drawings showing a diode as a semiconductor device according to a first embodiment of the present invention;

FIG. 2 is a drawing explaining perimeter in the semiconductor device of the first embodiment;

FIG. 3 is a drawing showing a modified example of the first embodiment;

FIG. 4 is a drawing showing a diode as a semiconductor device according to a second embodiment of the present invention;

FIG. 5 is a drawing showing a diode as a semiconductor device according to a third embodiment of the present invention; and

FIGS. 6A to 6C are drawings showing a conventional diode.

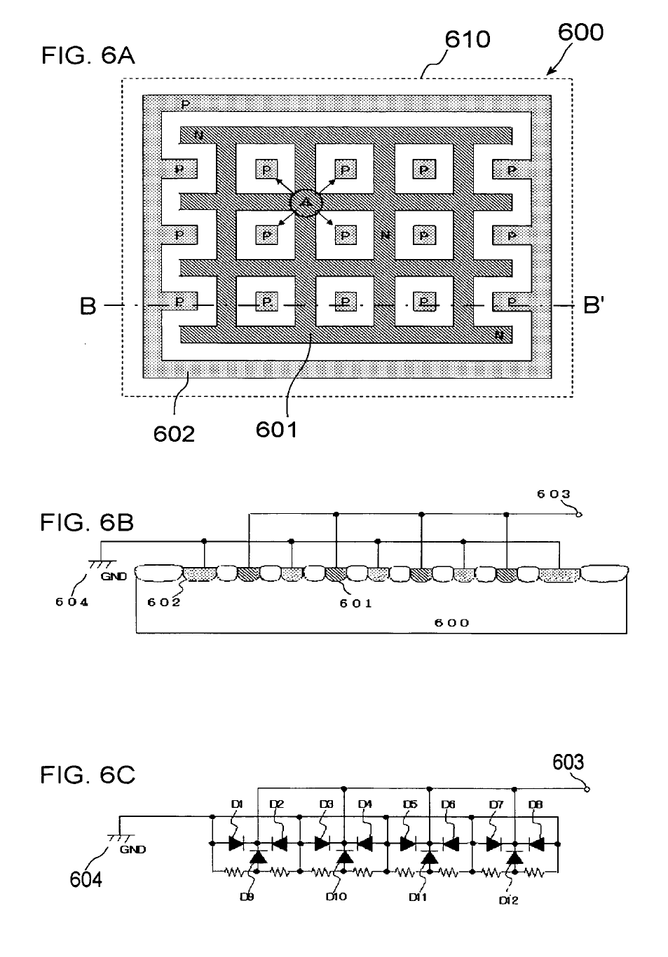

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The paragraphs below will detail a semiconductor device of the present invention referring to the attached drawings.

Any common components will be given with the same reference numerals, omitting repetitive explanations therefor.

### First Embodiment

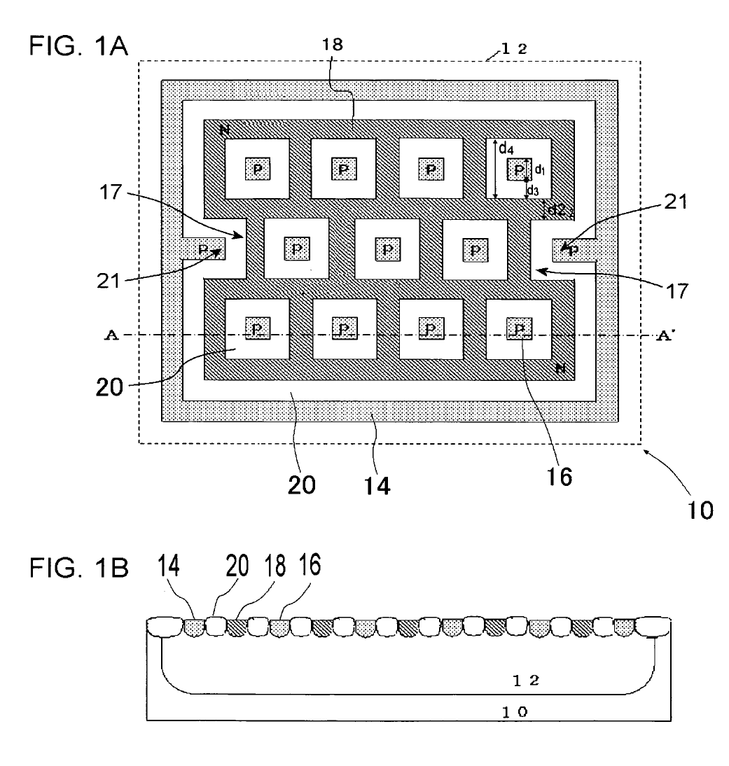

FIGS. 1A and 1B are drawings showing a diode as a semiconductor device according to a first embodiment of the present invention, wherein FIG. 1A shows a top view, and FIG. 1B shows a sectional view taken along line A-A′.

The diode shown in FIGS. 1A and 1B has a P⁺-type semiconductor substrate 10 as the first-conductivity-type semiconductor substrate, and a P-well 12 as the first-conductivity-type buried diffusion layer, formed by diffusing therein an impurity.

The P-well 12 has an outer peripheral P⁺-type diffusion layer 14 formed therein as the first-conductivity-type outer peripheral high concentration diffusion layer, formed by diffusing an impurity along the outer periphery of the P-well 12 with a concentration higher than that in the P-well 12.

In the regions surrounded by the outer peripheral P⁺-type diffusion layer 14, P⁺-type diffusion layers 16 are formed as having a square outer peripheral profile, arrayed so that the centers thereof are aligned in line in one direction in a plan view, and so that every second centers thereof are aligned in line in the direction normal to the one direction. Each of the P⁺-type diffusion layers 16 is formed by diffusing an impurity with a concentration higher than that in the P-well 12.

Between the outer peripheral P⁺-type diffusion layer 14 and the P⁺-type diffusion layers 16, and between the every adjacent P⁺-type diffusion layers 16, there is formed N⁺-type diffusion layer 18 as the second-conductivity-type high concentration diffusion layers, continuously formed by diffusing an impurity with a high concentration. It is to be noted herein that “continuously” means a pattern having no interruption.

Between the outer peripheral P⁺-type diffusion layer 14 and the N⁺-type diffusion layer 18, and between the P⁺-type diffusion layers 16 and the N⁺-type diffusion layer 18, there are formed insulating layers 20 having a predetermined width. In particular as shown in FIG. 1B, the insulating layers 20 electrically isolate the outer peripheral P⁺-type diffusion layer 14 from the N⁺-type diffusion layer 18, and isolate the P⁺-type diffusion layers 16 from the N⁺-type diffusion layer 18, respectively, serving as isolation regions of the both.

The N⁺-type diffusion layer 18 is connected as cathodes, and the outer peripheral P⁺-type diffusion layer 14 and the plurality of P⁺-type diffusion layers 16 are connected as anodes.

It is also allowable that the inner peripheral portion of the outer peripheral P⁺-type diffusion layer 14 may be formed as being projected (projections 21), at positions opposing to recessed portions (recesses 17) formed in the outer peripheral portion of the N⁺-type diffusion layer 18. This makes it possible to increase the total length (also referred to as “perimeter”) of the opposing edges of both diffusion layers within the outer peripheral portion. This further makes it possible to improve the surge voltage resistance even in a semiconductor device of the same area.

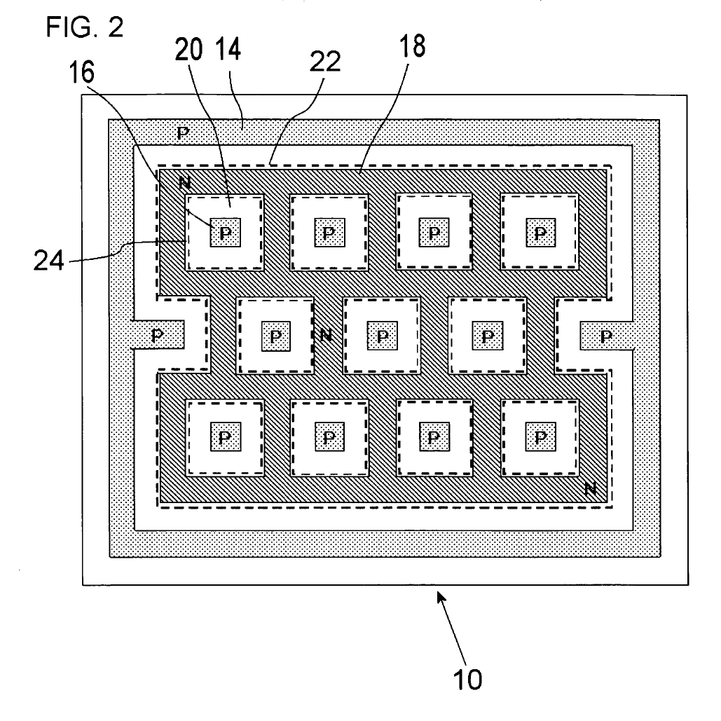

It is to be noted that the perimeter mentioned herein means, as shown in FIG. 2, the perimeter of the N⁺-type diffusion layer 18 in contact with the insulating layer 20 arranged along the inner periphery of the outer peripheral P⁺-type diffusion layer 14, and the perimeter of the N⁺-type diffusion layer 18 in contact with the individual insulating layers 20 arranged around the P⁺-type diffusion layers 16 arranged with an array pattern.

In the device shown in FIG. 1A, it is also preferable that the distance between the P⁺-type diffusion layers 16 and the N⁺-type diffusion layer 18, that is, the width of the insulating layers 20 formed around the P⁺-type diffusion layers 16, is uniform in view of avoiding current concentration in the N⁺-type diffusion layers 18. Similarly, it is also preferable that the insulating layer 20 formed on the inner peripheral side of the outer peripheral P⁺-type diffusion layer 14 have a uniform width over the entire region of the device. It is also allowable that both insulating layers 20 have the same width. Also the N⁺-type diffusion layers 18 may have a uniform width over the entire region of the device, in view that any non-uniform portion occurred therein may have current concentrated thereto from the P⁺-type diffusion layers 16 (and from the outer peripheral P⁺-type diffusion layer 14).

A relation of d1=d3 may hold, assuming the width of the P⁺-type diffusion layers 16 as d1, and the width of the insulating layers 20 as d3. Also a relation of d1=d2 may hold, assuming the width of the N⁺-type diffusion layers 18 as d2.

A relation of d1=d2=d3 preferably holds in view of avoiding concentration of current in the N⁺-type diffusion layers 18. Assuming now the distance of the N⁺-type diffusion layers 18 as d4, the equation below may be satisfied:
d1=d2=d3=d4/3 (1)

By satisfying the equation (1) in the above, the width of both diffusion layers becomes equal to the distance between the P⁺-type diffusion layers 16 (or occasionally the outer peripheral P⁺-type diffusion layer 14) and the N⁺-type diffusion layers 18, without causing geometrical non-uniformity, so that it is made possible to uniformly spread the current from the P⁺-type diffusion layers 16, and to more effectively improve the surge voltage resistance.

Comparison of the perimeter in the conventional structure with the perimeter of the same-sized structure of this embodiment, while assuming d1=1 μm for example, gives 192 μm for the conventional structure, and 200 μm for the present embodiment. This means that even the same-sized diode can increase the perimeter, and makes it possible to obtain the above-described effects.

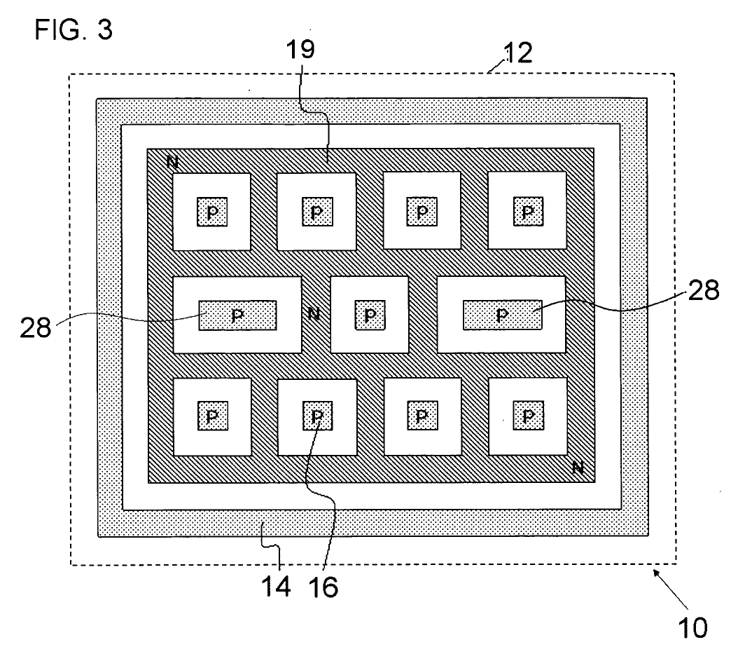

FIG. 3 is a drawing showing a modified example of the first embodiment.

The modified embodiment involves a configuration similar to that of the diode shown in FIG. 1A, except that an outermost N⁺-type diffusion layer 19 is formed to have a straight pattern, in place of providing the recesses to the edges of the N⁺-type diffusion layer 18, and that rectangular P⁺-type diffusion layers 28 are formed at positions adjacent to where the projections 21 of the outer peripheral P⁺-type diffusion layer 14 were formerly provided.

According to the first embodiment, the number of the P⁺-type diffusion layers 16 as the first-conductivity-type high concentration diffusion layer (and the outer peripheral P⁺-type diffusion layer 14), disposed around a single branching point (corner portion) of the N⁺-type diffusion layer 18 as the second-conductivity-type high concentration diffusion layer, can be reduced to as small as 3 or less, so that current concentrated at the individual branching points from the surrounding P⁺-type diffusion layers 16 can be moderated as compared with the conventional case, and the surge voltage resistance can be improved.

### Second Embodiment

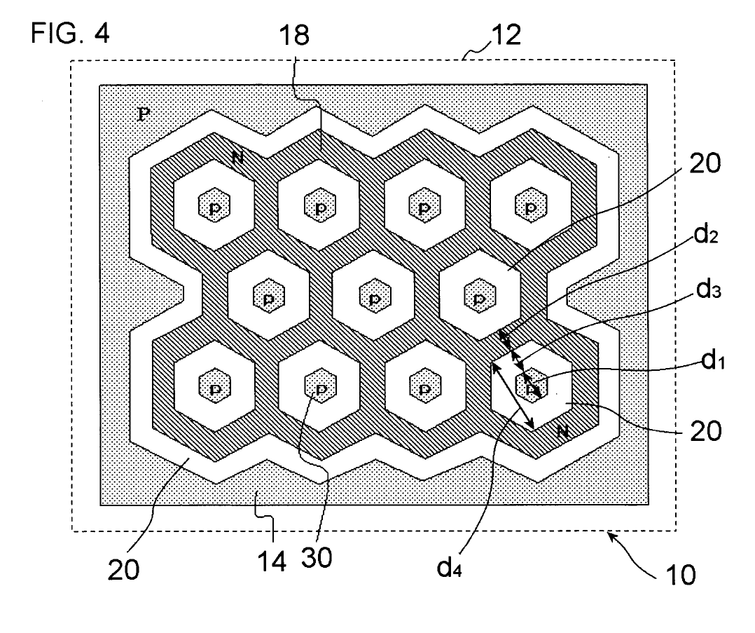

FIG. 4 is a drawing showing a diode as a semiconductor device according to the second embodiment of the present invention.

The second embodiment involves a configuration similar to that of the diode according to the first embodiment, except that P⁺-type diffusion layers 30 having a hexagonal outer peripheral profile are arranged in place of the square P⁺-type diffusion layers 16 shown in FIG. 1A.

In the second embodiment, it is also allowable to satisfy the equation (1) in the above, typically by assuming the width d1 of the P⁺-type diffusion layers 30 as the distance between the opposing edges of a hexagon, assuming the width d2 of the N⁺-type diffusion layer 18 as the distance between the adjacent insulating layers 20, assuming the distance d3 between the P⁺-type diffusion layers 30 (or the outer peripheral P⁺-type diffusion layer 14) and the N⁺-type diffusion layer 18 as the distance between each edge of the P⁺-type diffusion layers 30 and of the outer periphery of the insulating layer 20 opposing with the P⁺-type diffusion layers 30, and assuming the distance d4 of the N⁺-type diffusion layer 18 as the distance between the opposing edges of a hexagonal insulating layer surrounding a single P⁺-type diffusion layer 30.

According to the second embodiment, similarly to the first embodiment, the number of the P⁺-type diffusion layers 30 (and the outer peripheral P⁺-type diffusion layer 14), disposed around a single branching point (corner portion) of the N⁺-type diffusion layer 18, can be reduced to as small as 3 or less, so that the current concentrated at the individual branching points from the surrounding P⁺-type diffusion layers can be moderated as compared with the conventional case, and the surge voltage resistance can be improved.

### Third Embodiment

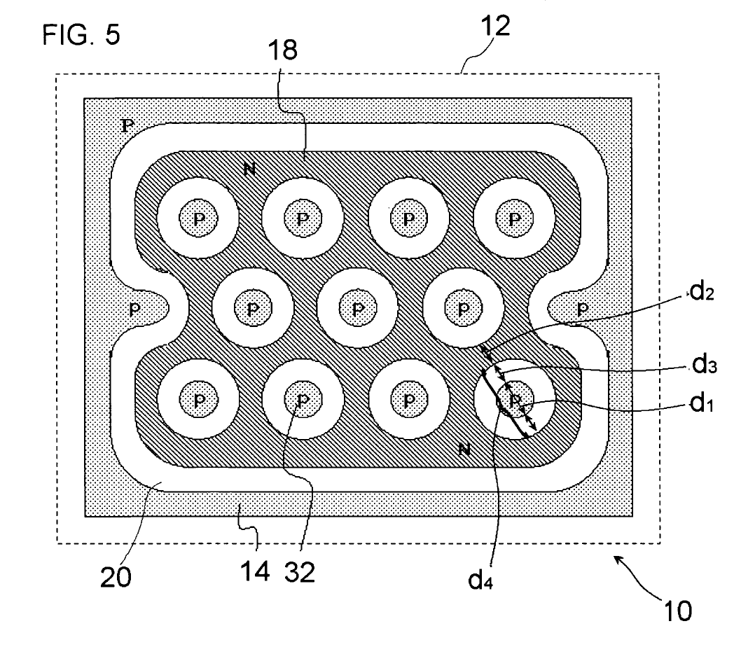

FIG. 5 is a drawing showing a diode as a semiconductor device according to the third embodiment of the present invention.

The third embodiment involves a configuration similar to that of the diode according to the first embodiment, except that P⁺-type diffusion layers 32 having a circular outer peripheral profile are arranged in place of the square P⁺-type diffusion layers 16 shown in FIG. 1A.

In the third embodiment, it is also allowable to satisfy the equation (1) in the above, typically by assuming the width d1 of the P⁺-type diffusion layers 32 as the diameter of the individual P⁺-type diffusion layer 32, assuming the width d2 of the N⁺-type diffusion layer 18 as the minimum distance between the adjacent insulating layers 20, assuming the distance d3 between the P⁺-type diffusion layers 32 (or the outer peripheral P⁺-type diffusion layer 14) and the N⁺-type diffusion layers 18 as the distance between each of the P⁺-type diffusion layers 32 and of the N⁺-type diffusion layer 18 measured on the line outwardly extended beyond the diameter of each P⁺-type diffusion layer 32, and assuming the distance d4 of the N⁺-type diffusion layer 18 as the diameter of the outer edge of each insulating layer 20 surrounding a single P⁺-type diffusion layer 32.

According to the third embodiment, similarly to the first embodiment, the number of the P⁺-type diffusion layers 32 (and outer peripheral P⁺-type diffusion layer 14), disposed around a single branching point (corner portion) of the N⁺-type diffusion layers 18, can be reduced to as small as 3 or less, so that the current concentrated at the individual branching points from the surrounding P⁺-type diffusion layers can be moderated as compared with the conventional case, and the surge voltage resistance can be improved. In particular, the individual diffusion layers and the insulating layers formed with a circular geometry is successful in eliminating geometrical non-uniformity in the diode, and makes it possible to more effectively spread the current from the P⁺-type diffusion layers 32, and to more effectively improve the surge voltage resistance.

The present invention is by no means limited to the embodiments which have been described in the above.

For example, effects of the present invention can be obtained if the diode is configured by exchanging the P⁺-type diffusion layers and the N⁺-type diffusion layers. The P-well in this case will be replaced by an N-well.

The geometry of the P⁺-type diffusion layer, exemplified as square (and rectangle), hexagon and circle in the above, is not limited thereto, allowing any other geometries provided that they are capable of uniformly spreading the current.

It is apparent that the present invention is not limited to the above embodiments, that may be modified and changed without departing from the scope and spirit of the invention.

What is claimed is:

1. A semiconductor device comprising:
a first-conductivity-type outer peripheral high concentration diffusion layer formed in a first-conductivity-type semiconductor substrate by diffusing therein an impurity with a high concentration along the outer periphery of a predetermined region;
first-conductivity-type high concentration diffusion layers formed in regions surrounded by said first-conductivity-type outer peripheral high concentration diffusion layer, by diffusing an impurity with a high concentration, arranged so that the centers thereof are aligned in line in one direction in a plan view, and so that every second centers thereof are aligned in line in the direction normal to the one direction; and
second-conductivity-type high concentration diffusion layers continuously formed between said first-conductivity-type outer peripheral high concentration diffusion layer and said first-conductivity-type high concentration diffusion layers, and between adjacent ones of said first-conductivity-type high concentration diffusion layers, by diffusing an impurity with a high concentration.

2. The semiconductor device according to claim 1, comprising:
a first-conductivity-type buried diffusion layer formed in a first-conductivity-type semiconductor substrate by diffusing therein an impurity;
a first-conductivity-type outer peripheral high concentration diffusion layer formed along the outer periphery of said first-conductivity-type buried diffusion layer, by diffusing an impurity with a concentration higher than that in said first-conductivity-type buried diffusion layer;
first-conductivity-type high concentration diffusion layers formed in regions surrounded by said first-conductivity-type outer peripheral high concentration diffusion layer, by diffusing an impurity with a concentration higher than that in said first-conductivity-type buried diffusion layer, arranged so that the centers thereof are aligned in line in one direction in a plan view, and so that every second centers thereof are aligned in line in the direction normal to the one direction; and
second-conductivity-type high concentration diffusion layers continuously formed between said first-conductivity-type outer peripheral high concentration diffusion layer and said first-conductivity-type high concentration diffusion layers, and between adjacent ones of said first-conductivity-type high concentration diffusion layers, by diffusing an impurity with a high concentration.

3. The semiconductor device according claim 1, wherein the inner peripheral portion of said first-conductivity-type outer peripheral high concentration diffusion layer is formed as being projected, in a plan view, at a position opposing to a recessed portion configured by the outer peripheral portion of said second-conductivity-type high concentration diffusion layers.

4. The semiconductor device according to claim 1, wherein each of said first-conductivity-type high concentration diffusion layers is formed to have a square outer peripheral profile.

5. The semiconductor device according to claim 1, wherein each of said first-conductivity-type high concentration diffusion layers is formed to have a hexagonal outer peripheral profile.

6. The semiconductor device according to claim 1, wherein each of said first-conductivity-type high concentration diffusion layers is formed to have a circular outer peripheral profile.

7. The semiconductor device according to claim 1, wherein distance between said first-conductivity-type high concentration diffusion layers and said second-conductivity-type high concentration diffusion layers is uniform over the entire region of the device.

8. The semiconductor device according to claim 1, wherein width of said second-conductivity-type high concentration diffusion layers is uniform over the entire region of the device.

9. The semiconductor device according to claim 1, wherein the width of said first-conductivity-type high concentration diffusion layers is equal to the distance between said first-conductivity-type high concentration diffusion layers and said second-conductivity-type high concentration diffusion layers.

10. The semiconductor device according to claim 7, wherein the formula (1) below:
d1=d2=d3=d4/3 (1)
holds, assuming the width of said first-conductivity-type high concentration diffusion layers as d1, the width of said second-conductivity-type high concentration diffusion layer as d2, the distance between said first-conductivity-type high concentration diffusion layers and said second-conductivity-type high concentration diffusion layers as d3, and the distance of said second-conductivity-type high concentration diffusion layers as d4.

11. The semiconductor device according to claim 8, wherein the formula (1) below:
d1=d2=d3=d4/3 (1)
holds, assuming the width of said first-conductivity-type high concentration diffusion layers as d1, the width of said second-conductivity-type high concentration diffusion layer as d2, the distance between said first-conductivity-type high concentration diffusion layers and said second-conductivity-type high concentration diffusion layers as d3, and the distance of said second-conductivity-type high concentration diffusion layers as d4.

12. The semiconductor device according to claim 9, wherein the formula (1) below:
d1=d2=d3=d4/3 (1)
holds, assuming the width of said first-conductivity-type high concentration diffusion layers as d, the width of said second-conductivity-type high concentration diffusion layer as d2, the distance between said first-conductivity-type high concentration diffusion layers and said second-conductivity-type high concentration diffusion layers as d3, and the distance of said second-conductivity-type high concentration diffusion layers as d4.
